(19) United States
(12) Patent Application Publication
(10) Pub. No.: US 2026/0097525 A1
(43) Pub. Date: Apr. 9, 2026

(54) COMPONENT MOUNTING MACHINE AND CONTACT DETERMINATION METHOD

(71) Applicant: FUJI CORPORATION, Chiryu (JP)

(72) Inventor: Yusaku KAGIMOTO, Anjo-shi (JP)

(73) Assignee: FUJI CORPORATION, Chiryu (JP)

(21) Appl. No.: 19/103,984

(22) PCT Filed: Sep. 29, 2022
(86) PCT No.: PCT/JP2022/036446

§ 371 Date: Feb. 14, 2025

(51) Int. Cl. B25J 15/06

(52) U.S. Cl. CPC B25J 15/0641

(57) ABSTRACT

A component mounter includes a head including multiple holders each holding a nozzle, and includes a fluid pressure circuit connected to the multiple holders, a sensor to detect at least one of a pressure and a flow rate of a fluid flowing through the fluid pressure circuit, and a determination section to set a threshold that increases as an absolute value of a pressure or a flow rate detected by the sensor, and determine that the component picked up by the nozzle is in contact with a board when the absolute value of the pressure detected by the sensor, an absolute value of a change amount of the detected pressure, or an absolute value of the detected flow rate or a change amount of the detected flow rate exceeds the threshold during the mounting operation after the predetermined timing.

### TECHNICAL FIELD

The present description discloses a component mounter and a contact determination method.

### BACKGROUND ART

Conventionally, there is known a component mounter that determines whether a component picked up by a nozzle is in contact with a board in a mounting operation and cheeks that the component is in contact with the board. For example, Patent Literature 1 discloses an apparatus including a head having multiple liftable holders, nozzles relatively and movably attached to the holders, a gas passage connected to the multiple holders and opened to the outside when the nozzles and holders are lowered together to press a component against a board, and the nozzles move a predetermined distance toward the holders, and a sensor for detecting a flow rate or a pressure of the gas flowing through the gas passage. In this component mounter, a gas flow rate or a gas pressure is monitored by a sensor, and when the gas passage is opened to the outside and the gas flow rate or the gas pressure exceeds a threshold (constant value), a component picked up by a nozzle is determined to be in contact with the board.

### CITATION LIST

### Patent Literature

Patent Literature 1: WO 2018/179317

### BRIEF SUMMARY

### Technical Problem

However, in the component mounter described above, multiple nozzles are held by a head, and multiple components are picked up in one cycle and mounted on a board. Accordingly, in such a component mounter, after the first component among the multiple components picked up by the multiple nozzles is mounted on a board, the other components can be mounted on the board in a short time. In a mounting operation of each component, whether a component is in contact with a board is determined by detecting by a sensor that a pressure in the gas passage is decreased or that a gas flow rate inside the gas passage is changed. When the pressure of the gas passage temporarily decreases, it takes a certain amount of time for the pressure to recover, and a state of pressure in the gas passage, in particular, during mounting of the first component among the multiple components on a board is significantly different from that during mounting of the next component on the board. In such a case, as in Patent Literature 1, when thresholds of a gas flow rate and a gas pressure are set to constant values, it may be difficult to detect a contact between a component picked up by a nozzle and a board.

A main object of the present disclosure is to enable more appropriate detection of a contact between a component and a board in a component mounter including a head holding multiple nozzles.

### Solution to Problem

The present disclosure employs following techniques to achieve a main object described above.

A component mounter of the present disclosure is
a component mounter that includes a head including multiple holders each relatively and movably holding a nozzle and sequentially performs mounting operations of mounting components picked up by multiple nozzles on a board, and includes
a fluid pressure circuit connected to the multiple holders,
a sensor configured to detect at least one of a pressure and a flow rate of a fluid flowing through the fluid pressure circuit, and
a determination section configured to set a threshold such that the threshold increases as an absolute value of a pressure or a flow rate detected by the sensor at a predetermined timing increases, and determine that the component picked up by the nozzle is in contact with the board when the absolute value of the pressure detected by the sensor, an absolute value of a change amount of the detected pressure, or an absolute value of the detected flow rate or a change amount of the detected flow rate exceeds the threshold during the mounting operation after the predetermined timing.

The component mounter determines that a component is in contact with a board when an absolute value of a pressure, an absolute value of a change amount of the pressure, or an absolute value of a flow rate or a change amount of the flow rate exceeds a threshold. The threshold at this time is set to a greater value as the absolute value of the pressure or the flow rate detected by the sensor increases at a predetermined timing. Thereby, it is possible to more appropriately detect a contact between a component and a board.

A contact determination method of the present disclosure is
a contact determination method to be applied to a component mounter that includes a head including multiple holders each relatively and movably holding a nozzle and sequentially performs mounting operations of mounting components picked up by the multiple nozzles on a board, the component mounter including a fluid pressure circuit connected to the multiple holders and a sensor configured to detect at least one of a pressure and a flow rate of a fluid flowing through the fluid pressure circuit, the contact determination method being for determining whether the component picked up by the nozzle is in contact with the board, and includes
setting a threshold such that the threshold increases as an absolute value of a pressure or a flow rate defected by the sensor at a predetermined timing increases, and determining that the component picked up by the nozzle is in contact with the board when the absolute value of the pressure detected by the sensor, an absolute value of a change amount of the detected pressure, or an absolute value of the detected flow rate or a change amount of the detected flow rate exceeds the threshold during the mounting operation after the predetermined timing.

The contact determination method achieves the same effect as the effect of the component mounter of the present disclosure.

### BRIEF DESCRIPTION OF DRAWINGS

FIG. 1 is a schematic configuration view of component mounter 10.

FIG. 2 is a schematic configuration view of mounting head 40.

FIG. 3 is a schematic configuration view of negative pressure supply device 70 and positive pressure supply device 80.

FIG. 4A is a view of a state in which nozzle section 61 of suction nozzle 60 is not pushed in toward nozzle holder 65.

FIG. 4B is a view of a state in which nozzle section 61 of suction nozzle 60 is pushed in toward nozzle holder 65 by a predetermined amount.

FIG. 5 is a block diagram illustrating an electrical connection relationship of control device 90.

FIG. 6 is a flowchart illustrating an example of a component mounting process routine.

FIG. 7 is a flowchart illustrating an example of a threshold setting process subroutine.

FIG. 8 is a diagram illustrating an example of a relational equation between a threshold and a pressure value.

FIG. 9A is a diagram illustrating an example of a pressure change model in a high-pressure state.

FIG. 9B is a diagram illustrating an example of a pressure change model in a low-pressure state.

FIG. 10 is a diagram illustrating a relationship between a mounting order and a deviation amount from an appropriate pushing-in amount.

### DESCRIPTION OF EMBODIMENTS

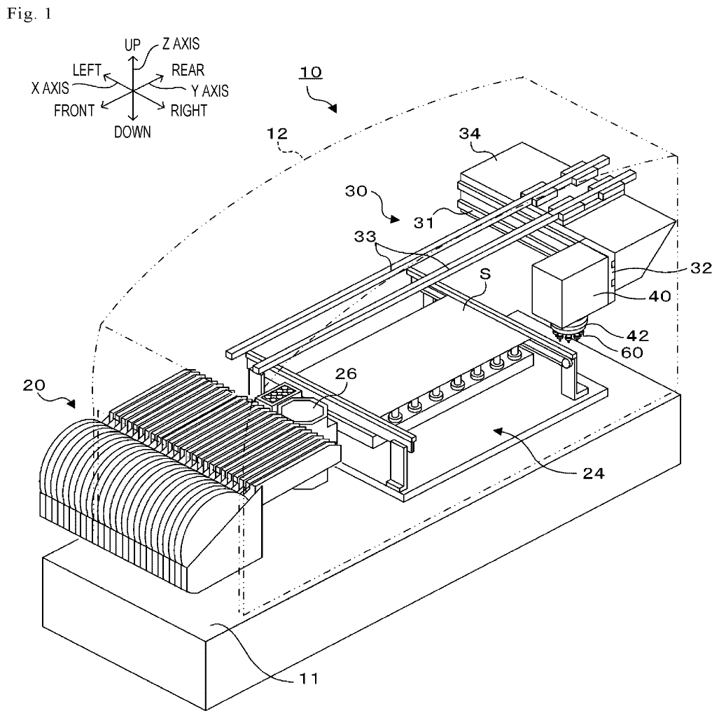

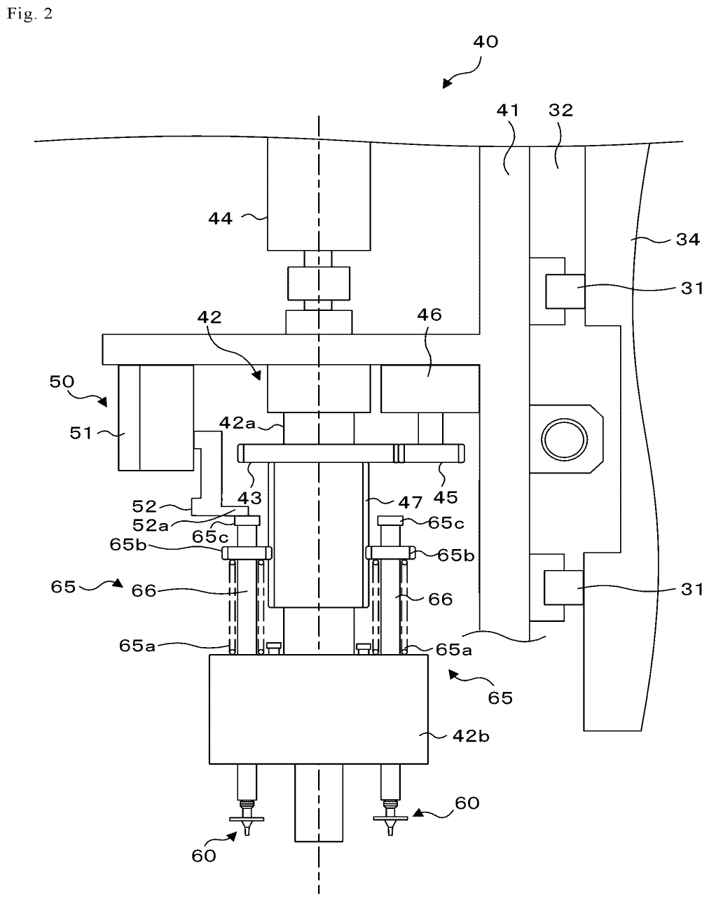

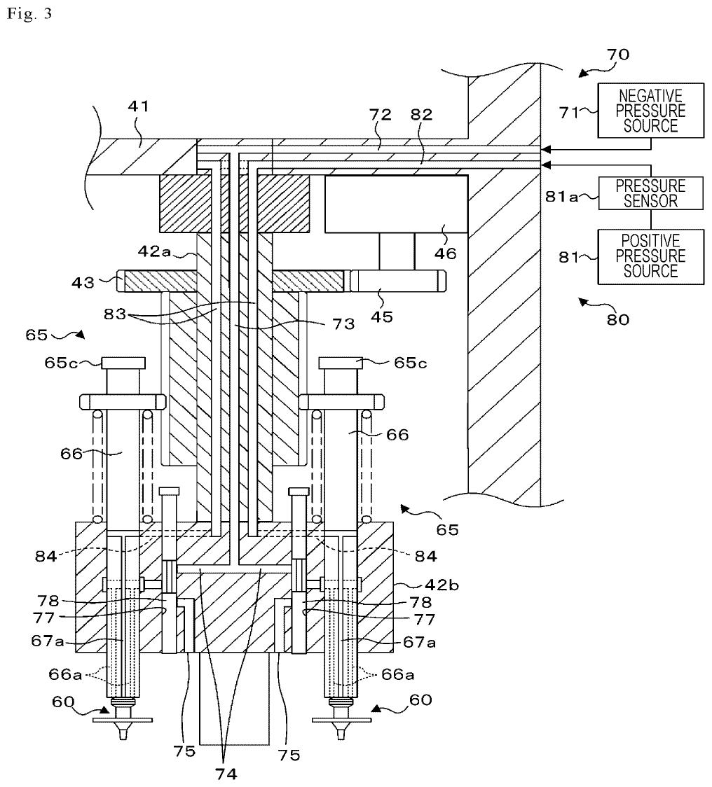

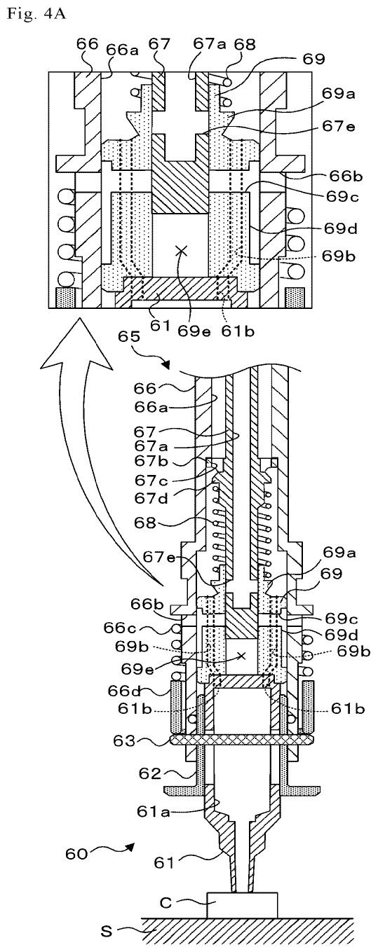

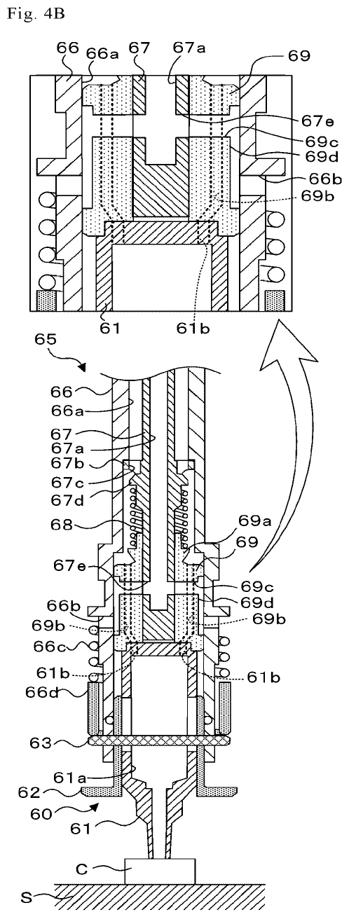

Next, embodiments of the present disclosure will be described with reference to the drawings. FIG. 1 is a schematic configuration view of component mounter 10. FIG. 2 is a schematic configuration view of mounting head 40. FIG. 3 is a schematic configuration view of negative pressure supply device 70 and positive pressure supply device 80. FIG. 4A is a view of a state in which nozzle section 61 of suction nozzle 60 is not pushed in toward nozzle holder 65. FIG. 4B is a view of a state in which nozzle section 61 of suction nozzle 60 is pushed in toward nozzle holder 65 by a predetermined amount. FIG. 5 is a block diagram illustrating an electrical connection relationship of control device 90. In FIG. 1, a left-right direction is an X-axis direction, a front (near)-rear (far) direction is a Y-axis direction, and an up-down direction is a Z-axis direction.

As illustrated in FIG. 1, component mounter 10 includes base 11, housing 12 supported by base 11, component supply device 20 that supplies component C to a component supply position, and board conveyance device 24 that conveys board S (an example of a mounting target). Further, component mounter 10 includes mounting head 40 that picks up component C supplied to the component supply position and mounts component C on board S, XY robot 30 that moves mounting head 40 in X-axis and Y-axis directions, and control device 90 (see FIG. 5) that controls all devices. Further, component mounter 10 includes part camera 26 for imaging a posture of component C held by mounting head 40, a mark camera (not illustrated) provided on mounting head 40 to read a positioning reference mark attached to board S, and the like, in addition to the components described above.

Component supply device 20 is configured as a tape feeder for supplying components C by feeding a tape on which components C are accommodated in accommodation sections formed at predetermined intervals.

As illustrated in FIG. 1, XY robot 30 includes a pair of left and right Y-axis guide rails 33 provided along a front-rear direction (Y-axis direction) on an upper stage section of housing 12. Y-axis slider 34 that spans a pair of left and right Y-axis guide rails 33 and is movable along Y-axis guide rails 33, X-axis guide rails 31 provided along a left and right direction (X-axis direction) on a side surface of Y-axis slider 34, and X-axis slider 32 that is movable along X-axis guide rails 31. X-axis slider 32 is movable by driving of X-axis motor 36 (see FIG. 5), and Y-axis slider 34 is movable by driving of Y-axis motor 38 (see FIG. 5). Mounting head 40 is attached to X-axis slider 32, and mounting head 40 is movable to any position on an XY plane as control device 90 drives and controls XY robot 30 (X-axis motor 36 and Y-axis motor 38).

As illustrated in FIG. 2 or FIG. 3, mounting head 40 includes head main body 42 in which multiple (20 in the present embodiment) nozzle holders 65 (only two nozzle holders are illustrated in FIGS. 2 and 3) are arranged at predetermined angular intervals (for example, 13 degree intervals) in a circumferential direction concentrically with a rotation axis, and suction nozzles 60 each being detachably attached to a lower end portion of each nozzle holder 65. Further, mounting head 40 includes R-axis motor 44 that rotates head main body 42 to rotate (revolve) multiple nozzle holders 65, Q-axis motor 46 that causes multiple nozzle holders 65 to rotate (spin), and lifting and lowering device 50 that lifts and lowers nozzle holders 65. Further, mounting head 40 includes negative pressure supply device 70 for supplying a negative pressure to nozzle section 61, and positive pressure supply device 80 for supplying a positive pressure to nozzle holders 65.

As illustrated in FIG. 2 or FIG. 3, head main body 42 includes frame 41 attached to X-axis slider 32, shaft section 42a rotatably supported by frame 41, and holder holding section 42b formed in a cylindrical shape having a diameter greater than a diameter of shaft section 42a and movably holding multiple nozzle holders 65 in the Z-axis direction. When R-axis motor 44 is driven, shaft section 42a and holder holding section 42b rotate, and thereby, multiple nozzle holders 65 rotate (revolve). Further, head main body 42 includes gear 43 that is coaxial with shaft section 42a and relatively and rotatably supported by shaft section 42a, and gear 47 that rotates according to the rotation of gear 43. Gear 43 meshes with gear 45 attached to a rotation shaft of Q-axis motor 46, and gear 47 meshes with gear 65b attached to each nozzle holder 65. When Q-axis motor 46 is driven, respective nozzle holders 65 and suction nozzles 60 respectively attached to nozzle holders 65 rotate (spin) in the same rotation direction by the same amount of rotation (rotation angle). Further, spring 65a is disposed between a lower surface of gear 65b and an upper surface of holder holding section 42b. Spring 65a biases nozzle holder 65 upward in the Z-axis direction.

Nozzle holder 65 is configured as a cylindrical member extending in the Z-axis direction, and as illustrated in FIG. 3, first gas passage 66a and second gas passage 67a are formed inside nozzle holder 65. Further, as illustrated in FIG. 2 or 3, nozzle holder 65 has an upper end portion on which horizontal section 65e is formed to extend in a radial direction.

As illustrated in FIG. 2, lifting and lowering device 50 includes linear motor 51 and Z-axis slider 52 which can be lifted and lowered in the Z-axis direction by driving of linear motor 51. Engagement section 52a, which can be engaged (here, in contact) with horizontal section 65c provided in nozzle holder 65 is formed in Z-axis slider 52. Engagement section 52a engages with horizontal section 65c of nozzle holder 65 located at a predetermined lifting and lowering position among multiple nozzle holders 65. When Z-axis slider 52 is lifted and lowered in a state where engagement section 52a is engaged with horizontal section 65c, nozzle holder 65 located at a lifting and lowering position is lifted and lowered according to the lifting and lowering. Since suction nozzle 60 is attached to nozzle holder 65, suction nozzle 60 is also lifted and lowered according to the lifting and lowering of nozzle holder 65. As multiple nozzle holders 65 are revolved by R-axis motor 44, nozzle holder 65 located at a lifting and lowering position among multiple nozzle holders 65 is switched.

Negative pressure supply device 70 is a device for independently supplying a negative pressure from the same negative pressure source 71 to multiple suction nozzles 60 respectively attached to multiple nozzle holders 65. As illustrated in FIG. 3, negative pressure supply device 70 includes negative pressure source 71 such as a vacuum pump, frame passage 72, head passage 73, negative pressure introduction passage 74, atmosphere introduction passage 75, spool hole 77, spool 78, and spool drive mechanism 79 (see FIG. 5). Frame passage 72 is formed in frame 41 of mounting head 40 and is connected to negative pressure source 71. Head passage 73 communicates with frame passage 72 and is formed to extend along a central axis of mounting head 40. Negative pressure introduction passage 74 communicates with head passage 73, and multiple negative pressure introduction passages 74 are formed to extend radially from a center axis of holder holding section 42b. Multiple atmosphere introduction passage 75 are formed to correspond to negative pressure introduction passage 74 to communicate with a positive pressure source (here, atmosphere).

Spool 78 is a switching valve for causing either of corresponding negative pressure introduction passage 74 or atmosphere introduction passage 75 to selectively communicate with first gas passage 66a provided in each of multiple nozzle holders 65. First gas passage 66a communicates with a suction hole at a front end of nozzle section 61 of suction nozzle 60, which will be described below in detail. As illustrated in FIG. 3, spool 78 is a tubular member that is inserted into a corresponding one of spool holes 77 formed in holder holding section 42b so as to correspond to each of multiple nozzle holders 65. In this spool 78, a substantially central portion is diametrically reduced, and a periphery of the diametrically reduced portion in a space of spool hole 77 constitutes a path for a negative pressure supplied from negative pressure source 71. Spool 78 causes first gas passage 66a to communicate with negative pressure introduction passage 74 and blocks the communication between first gas passage 66a and atmosphere introduction passage 75 in a state where spool 78 moves upward (a state illustrated in FIG. 3). Meanwhile, in a state where spool 78 moves downward, spool 78 blocks the communication between first gas passage 66a and negative pressure introduction passage 74 and causes first gas passage 66a to communicate with atmosphere introduction passage 75. By outputting a driving force to move up and down spool 78, spool drive mechanism 79 switches whether spool 78 causes either of negative pressure introduction passage 74 or atmosphere introduction passage 75 to communicate with first gas passage 66a.

Positive pressure supply device 80 is a device for supplying a positive pressure to second gas passage 67a provided in each of multiple nozzle holders 65. As illustrated in FIG. 3, positive pressure supply device 80 includes positive pressure source 81 such as a compressor, pressure sensor 81a, frame passage 82, head passage 83, and positive pressure introduction passage 84. Pressure sensor 81a is connected to positive pressure source 81 and detects a pressure of gas (here, air) supplied from positive pressure source 81 and flowing through second gas passage 67a. Frame passage 82 is formed at a position different from frame passage 72 inside frame 41 of mounting head 40 and is connected to pressure sensor 81a and positive pressure source 81. Head passage 83 communicates with frame passage 82 and is formed to extend along a center axis direction of mounting head 40. Head passage 83 has a ring shape centered at head passage 73 as viewed from above and extends in an up-down direction to surround a periphery of head passage 83 while being separated from head passage 73. Positive pressure introduction passage 84 communicates with head passage 83, and multiple positive pressure introduction passages 84 are formed to extend from a center axis side of holder holding section 42b toward an outer side of holder holding section 42b. Each of multiple positive pressure introduction passages 84 is formed to correspond to each of multiple nozzle holders 65 and communicates with second gas passage 67a of corresponding nozzle holder 65. All of multiple positive pressure introduction passages 84 are formed to avoid negative pressure introduction passage 74 and spool hole 77. All of frame passage 82, head passage 83, positive pressure introduction passage 84, and second gas passage 67a do not communicate with all of frame passage 72, head passage 73, negative pressure introduction passage 74, atmosphere introduction passage 75, spool hole 77, and first gas passage 66a. That is, paths of a negative pressure and a positive pressure (atmosphere) of negative pressure supply device 70 are independent of a path of a positive pressure of positive pressure supply device 80.

The inside of nozzle holder 65 and suction nozzle 60 will be described in detail with reference to FIGS. 4A and 4B. FIG. 4A is a view of a state in which nozzle section 61 of suction nozzle 60 is not pushed in toward nozzle holder 65 side (upward in FIG. 4A), and FIG. 4B is a view illustrating a state in which nozzle section 61 is pushed in toward nozzle holder 65 by a predetermined amount. As illustrated in FIGS. 4A and 4B, suction nozzle 60 includes nozzle section 61, tubular section 62 having a diameter greater than a diameter of nozzle section 61, and pin 63. Nozzle section 61 is a cylindrical body and picks up component C by supplying a negative pressure to nozzle section passage 61a in the inside in a state where a suction hole of a front end (a lower end of FIGS. 4A and 4B) is in contact with component C. Multiple nozzle section branch passages 61b are formed on an upper end of nozzle section 61. Nozzle section branch passage 61b is a through hole in an up-down direction and causes nozzle section passage 61a to communicate with an upper side of nozzle section 61. Multiple nozzle section branch passages 61b are formed circumferentially at equal intervals as viewed from above. Although each of FIGS. 4A and 4B illustrates two nozzle section branch passages 61b, for example, four nozzle section branch passages 61b may be provided. Although one or more nozzle section branch passages 61b may be provided, multiple nozzle section branch passages 61b are preferably provided such that a negative pressure from negative pressure source 71 is easily applied to a suction hole of a front end of nozzle section 61. Tubular section 62 is attached to an outer circumference of nozzle section 61 and has a flange section. An outer diameter of tubular section 62 is less than an inner diameter of a lower end portion of outer tube 66, and tubular section 62 and nozzle section 61 can be inserted into the inside of outer tube 66. Pin 63 penetrates nozzle section 61 and tubular section 62 in a radial direction (left-right directions of FIGS. 4A and 4B). A pair of elongated holes, which are elongated in an up-down direction, is provided in nozzle section 61, and pin 63 penetrates the pair of elongated holes. Accordingly, pin 63 can move up and down along the elongated holes with respect to nozzle section 61. Thereby, pin 63 holds both nozzle section 61 and tubular section 62 such that nozzle section 61 is not dislocated from tubular section 62 while allowing nozzle section 61 to move up and down with respect to tubular section 62.

Nozzle holder 65 includes outer tube 66, inner tube 67 on an inner side of outer tube 66, spring 68, and valve 69. Inner tube 67 is inserted into an inner side of outer tube 66, and a space between an inner circumferential surface of outer tube 66 and an outer circumferential surface of inner tube 67 serves as first gas passage 66a described above. First gas passage 66a extends in an up-down direction. First gas passage 66a constitutes a space provided inside nozzle holder 65 to cause gas to flow in the up-down direction therein. Further, upper sides of nozzle section 61 and tubular section 62 of suction nozzle 60 are inserted into the inside of outer tube 66 from below. Tubular pressing member 66d and spring 66c configured to bias pressing member 66d downward are attached to an outer side of outer tube 66. A slit is formed on outer tube 66 to extend upward from a lower end of outer tube 66 and thereafter toward a circumferential direction of outer tube 66. When suction nozzle 60 is attached to nozzle holder 65, suction nozzle 60 is lifted to cause tubular section 62 to be inserted into the inside of outer tube 66 and then suction nozzle 60 revolves in a circumferential direction. Thereby, pin 63 moves upward and circumferentially within a slit of outer tube 66 until pin 63 reaches a dead end of the slit, and suction nozzle 60 is attached to outer tube 66. In this state, pressing member 66d presses down pin 63 by a biasing force of spring 66c. Thereby, pressing member 66d prevents pin 63 from being dislocated from the slit of outer tube 66 to thereby prevent suction nozzle 60 from being dislocated from outer tube 66. Further, outer tube 66 has leak hole 66b slightly above an attachment position of suction nozzle 60. Leak hole 66b is a through hole that penetrates outer tube 66 horizontally (vertically in an up-down direction) and is opened to the outside of outer tube 66. Leak hole 66b is formed to cause an inner side of outer tube 66 to communicate with an outer side of outer tube 66 in a radial direction.

An inner space of inner tube 67 constitutes second gas passage 67a described above. Second gas passage 67a extends in an up-down direction. Second gas passage 67a is a space provided inside nozzle holder 65 such that gas flows in the up-down direction therein. Inner tube 67 includes second gas passage 67a, flange section 67b, through hole 67c, protruding section 67d, and opening 67e. Flange section 67b is in contact with a portion up and down in which an inner circumferential surface of outer tube 66 is narrowed and is engaged with the portion. Thereby, even though a biasing force of spring 68 is applied, inner tube 67 receives a downward reaction force from outer tube 66, and accordingly, outer tube 66 is prevented from moving upward with respect to inner tube 67. Through hole 67c is a hole penetrating flange section 67b up and down, and multiple through holes 67c are provided at equal intervals on a circumference as viewed from above. Although each of FIGS. 4A and 4B illustrates two through holes 67c, for example, four through holes 67c may also be formed. By providing one or more through holes 67e, a portion of first gas passage 66a above flange section 67b communicates with a portion of first gas passage 66a below flange section 67b. Protruding section 67d is a section formed to protrude outward in a radial direction below flange section 67b in inner tube 67, and a lower surface of protruding section 67d is in contact with an upper end of spring 68. Opening 67e is a through hole that horizontally (vertically in an up-down direction) penetrates inner tube 67, and is formed to cause second gas passage 67a inside inner tube 67 to communicate with an outer circumferential surface side of inner tube 67. Opening 67e is formed around a dead end of a lower end of second gas passage 67a. Opening 67e is formed to cause an inner side of inner tube 67 to communicate with an outer side of inner tube 67 in a radial direction.

Valve 69 is a switching valve configured to switch between communication and non-communication of leak hole 66b of outer tube 66 with opening 67e of inner tube 67. Valve 69 is a tubular member having a space in the inside thereof, and a lower end of inner tube 67 is inserted into the inside to be slidable up and down. Valve 69 includes protruding section 69a, valve passage 69b, communication hole 69c, diameter reduction section 69d, and space 69e. Protruding section 69a is a section formed to protrude outward in a radial direction in valve 69, and an upper surface of protruding section 69a is in contact with a lower end of spring 68. Thereby, spring 68 is vertically sandwiched and held between protruding section 67d of inner tube 67 and protruding section 69a of valve 69. Thereby, spring 68 biases nozzle section 61 downward through valve 69. More specifically, spring 68 biases nozzle section 61 downward while allowing nozzle section 61 to be pushed in toward nozzle holder 65 (upward in FIG. 4).

Valve passage 69b is a hole penetrating valve 69 up and down. Valve passage 69b has an upper end communicating with first gas passage 668 and has a lower end communicating with nozzle section branch passage 61b. Valve passage 69b is formed to correspond to nozzle section branch passage 61b. First gas passage 66a communicates with nozzle section passage 61a by valve passage 69b and nozzle section branch passage 61b, and a negative pressure or a positive pressure (atmosphere) from first gas passage 66a is applied to a front end of nozzle section 61. Communication hole 69c is a through hole penetrating valve 69 horizontally (vertically in an up-down direction) and is formed to cause an inner side of valve 69 to communicate with an outer side of valve 69. Communication hole 69c is formed to cause the inside of valve 69 to communicate with the outside of valve 69 in a radial direction. Diameter reduction section 69d is a section formed to radially reduce a part of valve 69 and causes a space on an outer circumferential surface side of valve 69, which is generated by radially reducing valve 69, to communicate with communication hole 69c. Diameter reduction section 69d is formed to maintain communication between leak hole 66b and communication hole 69c even when valve 69 moves up and down and to have a predetermined length in an up-down direction according to a movable range of valve 69. Communication hole 69c and diameter reduction section 69d are formed so as not to communicate with valve passage 69b. More specifically, valve passage 69b penetrates up and down a position at which neither communication hole 69c nor diameter reduction portion 69d is present when viewed from above and which is separated from them. Further, communication hole 69c is formed to correspond to leak hole 66b and opening 67e such that leak hole 66b can communicate with opening 67e. Although each of FIGS. 4A and 4B illustrates two leak holes 66b, two openings 67e, and two communication holes 69c, each of leak hole 66b, opening 67e, and communication hole 69e only needs to be provided in one or more and may be provided in, for example, four. Space 69e is a space on a lower side of a lower end of inner tube 67 in a state where valve 69 is not pushed in upward. Space 69e is surrounded by an upper surface of nozzle section 61, an inner circumferential surface of valve 69, and a lower end of inner tube 67. Because space 69e is present, valve 69 and nozzle section 61 are movable up and down with respect to inner tube 67.

Second gas passage 67a and opening 67e communicating with second gas passage 67a, communication hole 69c, diameter reduction section 69d, and leak hole 66b do not communicate with any of first gas passage 66a and through hole 67c communicating with first gas passage 66a, valve passage 69b, nozzle section branch passage 61b, and nozzle section passage 61a.

Here, switching between communication and non-communication of leak hole 66b with opening 67e by valve 69 will be described. For example, in picking up component C, mounting component C, or the like, when nozzle holder 65 is lowered by lifting and lowering device 50, nozzle section 61 is also lowered according to the lowering of nozzle holder 65. Then, in a state where component C picked up by nozzle section 61 or a front end of nozzle section 61 is not in contact with another member, or a state where component C is in contact with another member but is not pressing against another member, valve 69 and nozzle section 61 are pressed downward by a biasing force of spring 68, resulting in a state illustrated in FIG. 4A. FIG. 4A illustrates a state where component C picked up by nozzle section 61 is in contact with board S but is not pressing against board S. In the state illustrated in FIG. 4A, a position of communication hole 69c of valve 69 is deviated from a position of opening 67e up and down, and accordingly, valve 69 blocks communication between leak hole 66b and opening 67e. Accordingly, a positive pressure supplied from positive pressure source 81 is supplied to second gas passage 67a, but gas does not flow out from second gas passage 67a. Thereby, the gas does not flow into second gas passage 67a and the respective passages of positive pressure supply device 80.

Meanwhile, in the state of FIG. 4A, when nozzle holler 65 is further lowered by lifting and lowering device 50, nozzle section 61 is pushed in toward nozzle holder 65 against a biasing force of spring 68. Thereby, nozzle section 61 and valve 69 move upward with respect to outer tube 66 and inner tube 67. Accordingly, communication hole 69c of valve 69 approaches opening 67e of inner tube 67. Then, when a pushing-in amount of nozzle section 61 reaches a predetermined amount, communication hole 69c of valve 69 communicates with opening 67e (FIG. 4B). In this state, second gas passage 67a communicates with the outside of outer tube 66 through opening 67e, communication hole 69c, diameter reduction section 69d, and leak hole 66b. Accordingly, gas flows from positive pressure source 81 to leak hole 66b and the outside of leak hole 66b due to a positive pressure supplied from positive pressure source 81. In this way, valve 69 switches between presence and absence of communication between second gas passage 67a and the outside depending on a state where a pushing-in amount of nozzle section 61 does not reach a predetermined amount (for example, FIG. 4A) and a state where the push-in amount of nozzle section 61 reaches the predetermined amount (for example. FIG. 4B). Then, depending on whether second gas passage 67a communicates with the outside, whether gas flows through a gas passage (a gas passage from positive pressure source 81 to leak bole 66b) including second gas passage 67a is changed. Accordingly, as pressure sensor 81a detects a change in pressure of the gas, component mounter 10 can detect whether component C picked up by suction nozzle 60 (nozzle section 61) is in contact with board S (whether component C picked up by suction nozzle 60 is pushed in to board S by an appropriate amount).

In the present embodiment, frame passage 82, head passage 83, positive pressure introduction passage 84, and second gas passage 67a are collectively referred to as a fluid pressure circuit H.

As illustrated in FIG. 5, control device 90 is configured as a microprocessor including CPU 91 as a main element, and includes ROM 92, storage 93 (for example, HDD or SSD), RAM 94, input/output interface 95, and the like, in addition to CPU 91. These are connected to each other through bus 96. Control device 90 receives, through input/output interface 95, an image signal from part camera 26, an image signal from mark camera, a detection signal from X-axis position sensor 37 for detecting a position of X-axis slider 32 in the X-axis direction, a detection signal from Y-axis position sensor 39 for detecting a position of Y-axis slider 34 in the Y-axis direction, a detection signal from Z-axis position sensor 53 for detecting a position of Z-axis slider 52 in the Z-axis direction, a detection signal from pressure sensor 81a, and the like. Meanwhile, a control signal to component supply device 20, a control signal to board conveyance device 24, a drive signal to XY robot 30 (X-axis motor 36 and Y-axis motor 38), a drive signal to mounting head 40 (R-axis motor 44 or Q-axis motor 46, linear motor 51, and spool drive mechanism 79), and the like are output from control device 90 through input/output interface 95.

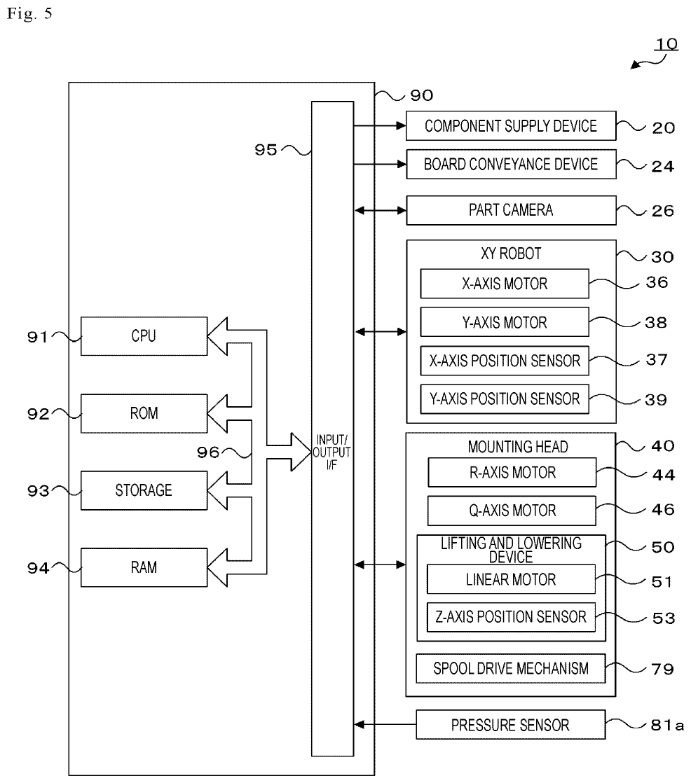

Next, an operation of component mounter 10 configured as described above, in particular, an operation of collecting component C and mounting component C on board S by mounting head 40 will be described with reference to FIG. 6 to FIG. 10. FIG. 6 is a flowchart illustrating an example of a component mounting process routine. A program for CPU 91 to execute the routine illustrated in FIG. 6 is stored in, for example, storage 93. For example, when a mounting instruction including component data related to component C which is mounted and a target mounting position of each component C is issued from a management device (not illustrated), CPU 91 starts the routine.

When the component mounting process routine starts, CPU 91 moves mounting head 40 above component supply device 20 and sequentially collects component C in each of the multiple nozzle sections 61 (S100). Specifically, CPU 91 causes lifting and lowering device 50 to lower nozzle holder 65 which is in a lifting and lowering position, causes spool drive mechanism 79 to switch spool 78 corresponding to nozzle holder 65 to apply a negative pressure to nozzle section 61, causes component C to be picked up by a front end of nozzle section 61, and then causes nozzle section 61 to be lifted. CPU 91 performs the process for nozzle sections 61 of all nozzle holders 65.

Next, CPU 91 moves each nozzle section 61 that picks up component C above part camera 26, causes part camera 26 to image component C, recognizes a position of component C picked up based on the obtained image, and corrects a target mounting position based on the recognized position (S105).

Subsequently, CPU 91 sets a target nozzle to mount component C on board S next among multiple suction nozzles 60 (S110). Then, CPU 91 controls XY robot 30 such that the target nozzle moves to the target mounting position on board S (S115). Then, CPU 91 controls lifting and lowering device 50 such that the lowering of the target nozzle starts (S120).

Next, CPU 91 acquires pressure P of fluid pressure circuit H from pressure sensor 81a and sets acquired pressure P to first pressure P1 (S125). Subsequently, CPU 91 waits until predetermined time ΔT1 elapses (S130). Here, the predetermined time ΔT1 is an interval at which CPU 91 acquires a pressure of fluid pressure circuit H from pressure sensor 81a and is set to several milliseconds (for example, approximately 1 ms). Subsequently, CPU 91 acquires pressure P of fluid pressure circuit H from pressure sensor 81a and sets acquired pressure P to second pressure P2 (S135). Then, CPU 91 determines whether an absolute value of second pressure P2 is less than an absolute value of first pressure P1 (S140).

When an absolute value of second pressure P2 is equal to or greater than an absolute value of first pressure P1, CPU 91 determines that component C picked up by a target nozzle is not yet in contact with board S, and makes a negative determination. The reason why CPU 91 determines in this way is that, in a state where component C picked up by the target nozzle is not in contact with board S, communication hole 69c does not communicate with opening 67e, and a pressure in fluid pressure circuit H does not decrease. Meanwhile, when the absolute value of second pressure P2 is less than the absolute value of first pressure P1, CPU 91 determines that component C picked up by the target nozzle starts to come into contact with board S and makes a positive determination. Making a determination by CPU 91 in this way is because, when component C picked up by the target nozzle starts to come into contact with board S, communication hole 69c starts to communicate with opening 67e, and the pressure in fluid pressure circuit H starts to decrease.

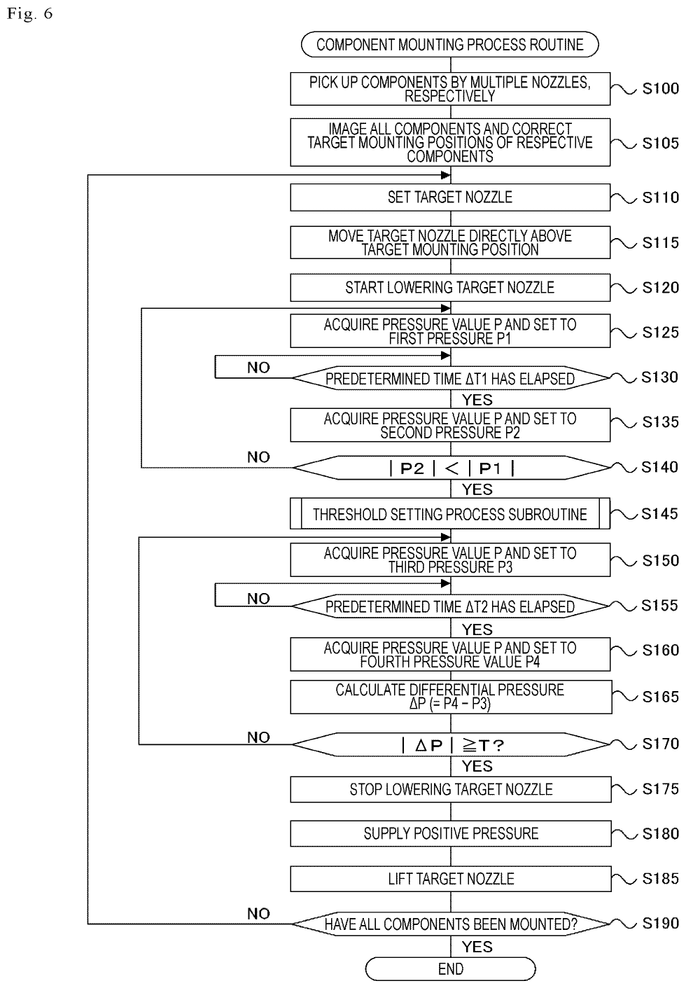

When the negative determination is made in S140, CPU 91 returns to S125 again. Meanwhile, when the positive determination is made in S140, CPU 91 performs a threshold setting process subroutine illustrated in FIG. 7 (S145), and sets threshold T for determining whether component C is in contact with board S. The threshold setting process subroutine will be described below.

Next, CPU 91 acquires pressure P in fluid pressure circuit H from pressure sensor 81a, and sets the acquired pressure P to third pressure P3 (S150). Subsequently, CPU 91 waits until predetermined time ΔT2 elapses (S155). Here, predetermined time ΔT2 is a time determined in advance and is a time (for example, approximately 4 ms) set to predetermined time ΔT1 or more. Then, CPU 91 acquires pressure P in fluid pressure circuit H from pressure sensor 81a and sets the acquired pressure P to fourth pressure P4 (S160).

Next, CPU 91 calculates differential pressure ΔP (=P4−P3) (S165). Subsequently, CPU 91 determines whether an absolute value of differential pressure ΔP is equal to or greater than threshold T (S170). When the absolute value of differential pressure ΔP is less than threshold T, CPU 91 determines that component C picked up by the target nozzle is not in contact with board S (component C picked up by the target nozzle is not pushed in to board S by an appropriate amount), and makes a negative determination. Meanwhile, when the absolute value of differential pressure ΔP is equal to or greater than a threshold, CPU 91 determines that component C picked up by the target nozzle is in contact with board S (component C picked up by the target nozzle is pushed in to board S by an appropriate amount), and makes a positive determination.

When the negative determination is made in S170, CPU 91 returns to S150 again. Meanwhile, when the positive determination is made in S170, CPU 91 controls lifting and lowering device 50 such that lowering of the target nozzle stops (S175). Subsequently, CPU 91 switches spool 78 corresponding to the target nozzle by using spool drive mechanism 79 to supply a positive pressure (atmosphere) to nozzle section 61 (S180). Thereby, pick-up of component C performed by the target nozzle is released. Then, CPU 91 controls lifting and lowering device 50 such that nozzle section 61 is lifted (S185). Next, CPU 91 determines whether all components C picked up by nozzle section 61 in S100 have been mounted on board S (S190). When a negative determination is made in S190, CPU 91 returns to S110 again and sets, as a target nozzle, suction nozzle 60 different from suction nozzle 60 set to the previous target nozzle. Meanwhile, when a positive determination is made in S190, CPU 91 ends the present routine.

Here, the threshold setting process subroutine will be described. When the threshold setting process subroutine starts, CPU 91 sets variable i to 1 (S200). Next, CPU 91 acquires pressure P in fluid pressure circuit H from pressure sensor 81a and sets pressure P to threshold setting i-th pressure Pi (S205). Subsequently, CPU 91 waits until predetermined time ΔT1 elapses (S210). Then, CPU 91 increments a value of variable i by 1 (S215).

Next, CPU 91 determines whether the value of variable i is greater than a predetermined number. Here, the predetermined number is a value determined in advance, for example, a value of approximately 4 to 10. When the value of variable i is equal to or less than the predetermined number, CPU 91 determines that the measured value of pressure sensor 81a is not yet acquired by a predetermined number, and makes a negative determination. Meanwhile, when the value of variable i is greater than the predetermined number, CPU 91 determines that the predetermined number of threshold setting i-th pressure Pi is already acquired, and makes a positive determination.

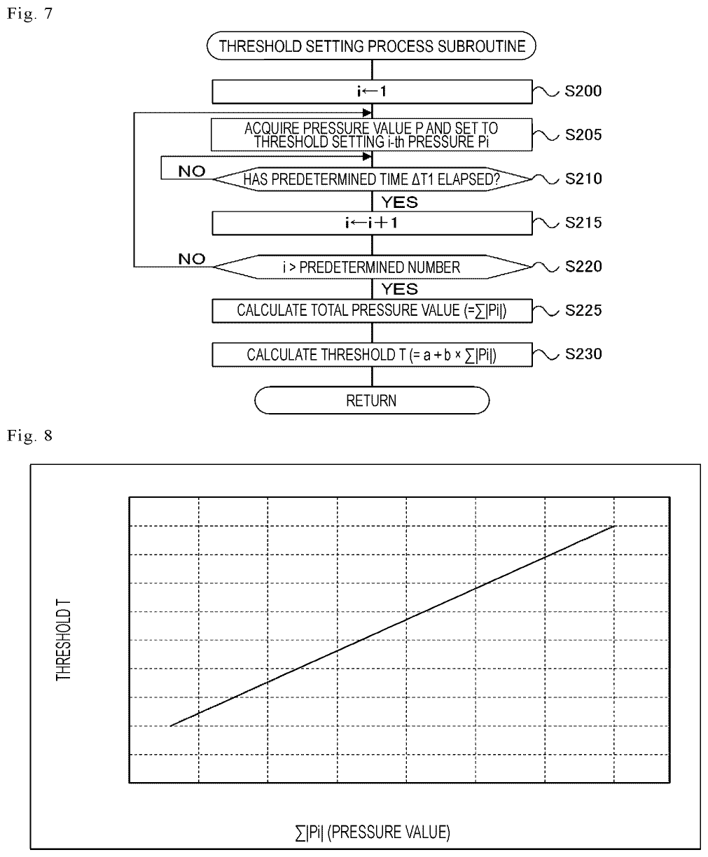

When a negative determination is made in S220, CPU 91 returns to S205 again. Meanwhile, when a positive determination is made in S220. CPU 91 calculates a total pressure value (=Σ|Pi|) (S225). Next, CPU 91 inserts the total pressure value (Σ|Pi|) into following Equation (1) to calculate threshold T (S230). As illustrated in FIG. 8, Equation (1) is a linear function determined such that, as a value of Σ|Pi| (pressure) increases, threshold T increases. The reason why threshold T is calculated as a linear function of a total pressure value is to reduce the influence of noise for threshold setting i-th pressure Pi.

$$T = a + b \times \sum \vert Pi \vert \qquad ( 1 )$$

A constant a and a proportional constant b are both greater than 0 and experimentally determined. After S230, CPU 91 returns to S150 of the component mounting process routine illustrated in FIG. 6.

As described above, component mounter 10 holds multiple suction nozzles 60 in mounting head 40 and picks up multiple components C and mounts multiple components C on board S in one cycle. Accordingly, after first component C among multiple components C picked up by multiple suction nozzles 60 is mounted on board S, component mounter 10 can mount other components C on board S in a short time. In the mounting operation of respective components C, determination on whether component C is in contact with board S is made by detecting, by pressure sensor 81a, that a pressure in fluid pressure circuit H is decreased due to fluid pressure circuit H being opened to the outside. When the pressure of fluid pressure circuit H is once decreased, it takes a certain amount of time for the pressure to recover, and accordingly, a pressure state within fluid pressure circuit H changes significantly, particularly when the first component among multiple components C is mounted on board S and when next component C is mounted on board S.

Further, in component mounter 10, by determining whether differential pressure ΔP exceeds threshold T, it is determined whether component C picked up by a target nozzle is in contact with board S, that is, whether component C picked up by the target nozzle is pushed in to board S by an appropriate amount. Accordingly, if threshold T is set to a constant value, the time from when component C picked up by suction nozzle 60 starts to come into contact with board S until differential pressure ΔP exceeds threshold T may be lengthened or shortened. This is because the way how pressure P in fluid pressure circuit H changes differs depending on immediately preceding pressure P in fluid pressure circuit H. Therefore, a pushing-in amount of component C with respect to board S is not stabilized, and the pushing-in amount of component C with respect to board S may be less than an appropriate amount or may be greater than the appropriate amount.

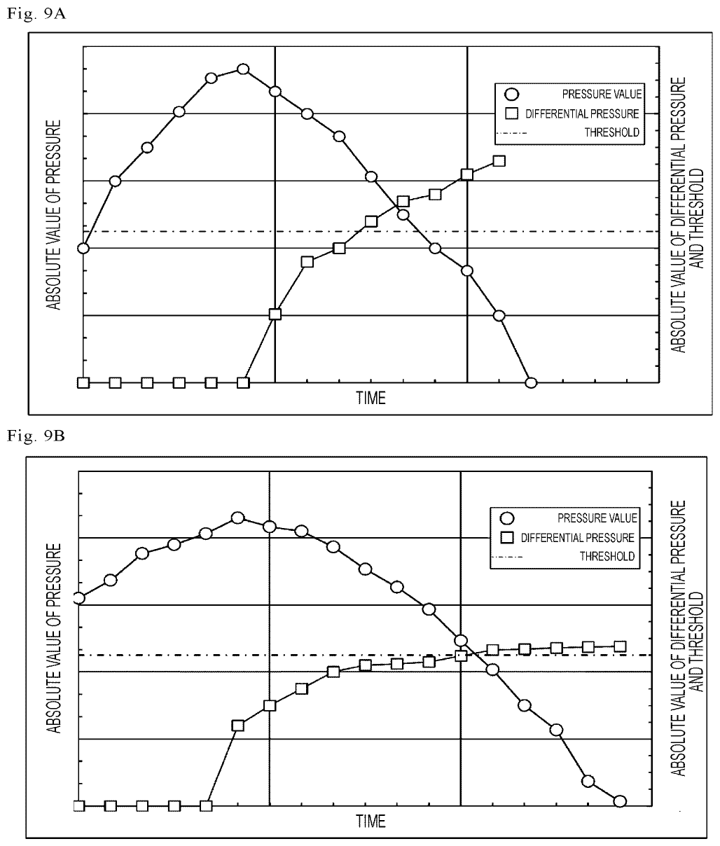

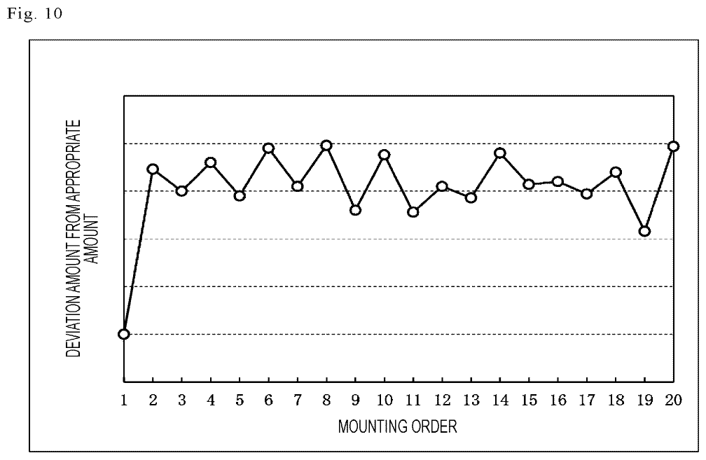

Here, an example in which the pushing-in amount of component C with respect to board S is not stable will be described. First, a case where the pushing-in amount of component C with respect to board S is less than the appropriate amount will be described. After S100 of the component mounting process routine, when first component C is mounted on board S, a measured value of pressure sensor 81a has a relatively high value. This is because the time from when component C is picked up by each suction nozzle 60 in S100 of the component mounting process routine until pressure P is acquired from pressure sensor 81a in S125 is relatively long, and pressure P in fluid pressure circuit His sufficiently increased during such time. In a state where an absolute value of a pressure in fluid pressure circuit H is high, pressure sensor 81a is greatly affected by noise, and a measured value is likely to vary. Further, in a state where the pressure in fluid pressure circuit H is high, a width of the pressure is large, and accordingly, the pressure in fluid pressure circuit H is likely to vary when communication hole 69c communicates with opening 67e. Accordingly, when threshold T is set to a constant value as illustrated in FIG. 9A, the time from when component C picked up by a target nozzle starts to come into contact with board S until differential pressure ΔP exceeds threshold T becomes a relatively short time. Therefore, as illustrated in FIG. 10, when a contact between component C and board S is detected by using threshold T having a constant value, a pushing-in amount of component C with respect to board S is likely to be less than an appropriate amount (refer to a deviation amount from the appropriate amount corresponding to a mounting order 1 in FIG. 10).

In FIG. 10, the fact that the deviation amount from the appropriate amount is 0 indicates that a pushing-in amount of component C with respect to board S is the appropriate amount. Further, the fact that the deviation amount from the appropriate amount is minus indicates that a pushing-in amount of component C with respect to board S is less than the appropriate amount. Further, the fact that the deviation amount from the appropriate amount is plus indicates that the pushing-in amount of component C with respect to board S is greater than the appropriate amount. The pushing-in amount of component C with respect to board S is calculated based on a difference between a defected value of Z-axis position sensor 53 at a point in time at which an absolute value of differential pressure ΔP exceeds threshold T and a reference value determined in advance in Z-axis position sensor 53.

Next, a case where the pushing-in amount of component C with respect to board S is greater than the appropriate amount will be described. When second and subsequent components C are mounted on board S, a measured value of pressure sensor 81a is a relatively low value. This is because the time from when component C picked up by certain suction nozzle 60 is mounted on board S until another suction nozzle 60 is set as a target nozzle and component C picked up by the target nozzle is mounted on board S is relatively short, and pressure P in fluid pressure circuit H does not increase too much during such time. In a state where an absolute value of a pressure in fluid pressure circuit H is low, pressure sensor 81a is less affected by noise, and a measured value is unlikely to vary. In a state where pressure P in fluid pressure circuit H is low, a width of the pressure is small, and accordingly, the pressure in fluid pressure circuit H is less likely to vary when communication hole 69c communicates with opening 67e. Accordingly, when threshold T is set to a constant value as illustrated in FIG. 9B, the time from when component C picked up by a target nozzle starts to come into contact with board S until an absolute value of differential pressure ΔP exceeds threshold T becomes a relatively long time. Therefore, as illustrated in FIG. 10, the pushing-in amount of component C with respect to board S is likely to increase more than the appropriate amount (refer to a deviation amount from the appropriate amount corresponding to a mounting order 2 to 20 in FIG. 10).

In this way, when a threshold is set to a constant value, a pushing-in amount of component C with respect to board S may be unstable. In contrast to this, component mounter 10 sets threshold T by using a linear function of pressure P (a measured value of pressure sensor 81a) in fluid pressure circuit H when component C picked up by suction nozzle 60 starts to come into contact with board S. Therefore, as compared with the case where threshold T is set to a constant value, a contact between component C picked up by suction nozzle 60 and board S can be appropriately detected. Thereby, the pushing-in amount of component C with respect to board S can be stabilized.

Here, a correspondence relationship between constituent components of a component mounter of the present embodiment and constituent components of a component mounter of the present disclosure will be described. Component mounter 10 of the present embodiment corresponds to a component mounter of the present disclosure, fluid pressure circuit H corresponds to a fluid pressure circuit, pressure sensor 81a corresponds to a sensor, and CPU 91 corresponds to a determination section.

In component mounter 10 described above, when an absolute value of a change amount of a pressure in fluid pressure circuit H exceeds a threshold, it is determined that component C is in contact with board S. Threshold T at this time is set to a greater value as an absolute value of a pressure detected by pressure sensor 81a increases at a predetermined timing. Thereby, a contact between component C and board S can be more appropriately detected.

Further, in component mounter 10, fluid pressure circuit H is opened to the outside as nozzle section 61 moves toward nozzle holder 65 by a predetermined amount. That is, the pressure in fluid pressure circuit H changes before and after a mounting operation, and accordingly, it is highly significant that threshold T is set based on an absolute value of a pressure detected by pressure sensor 81a at a predetermined timing.

In component mounter 10, CPU 91 sets threshold T by using Equation (1) representing a relationship between Σ|Pi| (a pressure detected by pressure sensor 81a at a predetermined timing) and threshold T. Thereby, threshold T can be set relatively easily.

In component mounter 10, mounting head 40 is a rotary head in which multiple nozzle holders 65 are disposed on a circumference and are rotatable in a circumferential direction. In the rotary head, before a pressure in a fluid pressure circuit recovers, multiple components C are continuously mounted on a board. Therefore, it is highly significant that a threshold can be set according to a pressure in a fluid pressure circuit at a predetermined timing.

It is needless to say that the present disclosure is not limited in any way to the embodiments described above, and the present disclosure can be embodied in various aspects as long as the aspects fall within the technical scope of the present disclosure.

In the embodiments described above, component mounter 10 includes pressure sensor 81a that detects a pressure of gas flowing through fluid pressure circuit H. However, component mounter 10 may include a flow rate sensor capable of detecting a gas flow rate in fluid pressure circuit H. In this case, it only needs to be determined whether component C picked up by a target nozzle is in contact with board S based on an absolute value of a change amount of a gas flow rate in fluid pressure circuit H. At this time, in S125, S135, S150, and S160 of a component mounting process routine, a flow rate of the gas flowing in fluid pressure circuit H only needs to be acquired from the flow rate sensor. Further, the gas flow rate may be acquired in S205 of the threshold setting process subroutine, a total value of a flow rate may be calculated in S225, and threshold T may be calculated by inserting the total value of the flow rate into a linear function which is the same as Equation (1) in S230.

Alternatively, in this case, it only needs to be determined whether component C picked up by a target nozzle is in contact with board S based on a gas flow rate in fluid pressure circuit H. At this time, in S125 and S135 of the component mounting process routine, a flow rate of gas flowing through fluid pressure circuit H only needs to be acquired from a flow rate sensor. Further, instead of the processes of S150 to S165 of the component mounting process routine, the flow rate of the gas flowing in fluid pressure circuit H at a certain point in time only needs to be acquired from the flow rate sensor. Further, the gas flow rate may be acquired in S205 of the threshold setting process subroutine, a total value of a flow rate may be calculated in S225, and threshold T may be calculated by inserting the total value of the flow rate into a linear function which is the same as Equation (1) in S230.

In the embodiments described above, a lifting and lowering position where lifting and lowering device 50 can lift and lower nozzle holder 65 is described as one location, but two or more lifting and lowering positions may be provided.

In the embodiments described above, a positive pressure is supplied to fluid pressure circuit H. However, a negative pressure may be supplied to fluid pressure circuit H by providing a negative pressure source instead of positive pressure source 81 illustrated in FIG. 3. In this case, a negative pressure may be supplied from a negative pressure source different from negative pressure source 71 to fluid pressure circuit H, or a negative pressure may be supplied from common negative pressure source 70 to fluid pressure circuit H. Also in this case, a pressure detected by pressure sensor 81a changes depending on whether component C picked up by a target nozzle is in contact with board S, and accordingly, CPU 91 can determine whether component C picked up by the target nozzle is in contact with board S.

In the embodiments described above, it is determined whether component C picked up by a target nozzle is in contact with board S based on an absolute value of a pressure change amount in fluid pressure circuit H. However, it may be determined whether component C picked up by the target nozzle is in contact with board S based on an absolute value of a pressure in fluid pressure circuit H. In this case, instead of the processes of S150 to S165 of a component mounting process routine, a pressure of gas flowing in fluid pressure circuit H at a certain point in time only needs to be acquired from pressure sensor 81a. Further, in S230 of a threshold setting process routine, threshold T only needs to be calculated by inserting a total pressure value into a linear function which is the same as Equation (1).

In the embodiments described above, in performing the process of S100 of a component mounting process routine, whether suction nozzle 60 (nozzle section 61) is in contact with component C may be determined.

In the embodiments described above, leak hole 66b is provided such that gas flows vertically in an up-down direction, but the embodiments are not limited thereto, and leak hole 66b may also be provided such that the gas flows in the up-down direction, for example. Further, without including leak hole 66b, communication hole 69c of valve 69 may be opened directly to the outside.

In the embodiments described above, an opening to the outside communicating with second gas passage 67a (here, leak hole 66b) is provided in nozzle holder 65, but the embodiments are not limited thereto. For example, the opening to the outside communicating with second gas passage 67a may be provided in suction nozzle 60.

In the embodiments described above, both first gas passage 66a and second gas passage 67a are provided such that gas flows in an up-down direction, but the embodiments are not limited thereto. For example, at least one of first gas passage 66a and second gas passage 67a may be provided such that the gas flows vertically in the up-down direction.

In the embodiments described above, air flows through first gas passage 66a and second gas passage 67a. However, positive pressure source 81 may supply an inert gas to fluid pressure circuit H.

In the embodiments described above, the present disclosure is described as component mounter 10 but may also use a contact determination method.

In the embodiments described above, mounting head 40 is a rotary head. However, mounting head 40 may be a head in which multiple nozzle holders 65 are disposed in a linear shape.

The present description also discloses a technical idea in which “the component mounter according to claim 1 or 2” is changed to “the component mounter according to any one of claims 1 to 3” in claim 4 initially filed. Further, the present description also discloses a technical idea in which “the component mounter according to claim 1 or 2” is changed to “the component mounter according to any one of claims 1 to 4” in claim 5 initially filed.

### INDUSTRIAL APPLICABILITY

The present disclosure can apply to a component mounter that mounts a component on a mounting target such as a board.

### REFERENCE SIGNS LIST

10 component mounter, 11 base, 12 housing, 20 component supply device, 24 board conveyance device, 26 part camera, 30 XY robot, 31 X-axis guide rail, 32 X-axis slider, 33 Y-axis guide rail, 34 Y-axis slider, 36 X-axis motor, 37 X-axis position sensor, 38 Y-axis motor, 39 Y-axis position sensor, 40 mounting head, 41 frame, 42 head main body, 42a shaft section, 42b holder holding section, 43 gear, 44 R-axis motor, 45 gear, 46 Q-axis motor, 47 gear, 50 lifting and lowering device, 51 linear motor, 52 Z-axis slider, 52a engagement section, 53 Z-axis position sensor, 60 suction nozzle, 61 nozzle section, 61a nozzle section passage, 61b nozzle section branch passage, 62 tubular section, 63 pin, 65 nozzle holder, 65a spring, 65b gear, 65c horizontal section, 66 outer tube, 66a first gas passage, 66b leak hole, 66c spring, 66d pressing member, 67 inner tube, 67a second gas passage, 67b flange section, 67c through hole, 67d protruding section, 67e opening, 68 spring, 69 valve, 69a protruding section, 69b valve passage, 69c communication hole, 69d diameter reduction section, 69e space, 70 negative pressure supply device, 71 negative pressure source, 72 frame passage, 73 head passage, 74 negative pressure introduction passage, 75 atmosphere introduction passage, 77 spool hole, 78 spool, 79 spool drive mechanism, 80 positive pressure supply device, 81 positive pressure source, 81a pressure sensor, 82 frame passage, 83 head passage, 84 positive pressure introduction passage, 90 control device, 91 CPU, 92 ROM, 93 storage, 94 RAM, 95 input/output interface, 96 bus, C component, H fluid pressure circuit, P pressure, P1 first pressure, P2 second pressure, P3 third pressure, P4 fourth pressure, Pi threshold setting i-th pressure, S board, a constant, b proportional constant, i variable, ΔP differential pressure.

1. A component mounter that includes a head including multiple holders each relatively and movably holding a nozzle and sequentially performs mounting operations of mounting components picked up by multiple nozzles on a board, the component mounter comprising:
a fluid pressure circuit connected to the multiple holders;
a sensor configured to detect at least one of a pressure and a flow rate of a fluid flowing through the fluid pressure circuit; and
a determination section configured to set a threshold such that the threshold increases as an absolute value of a pressure or a flow rate detected by the sensor at a predetermined timing increases, and determine that the component picked up by the nozzle is in contact with the board when the absolute value of the pressure detected by the sensor, an absolute value of a change amount of the detected pressure, or an absolute value of the detected flow rate or a change amount of the detected flow rate exceeds the threshold during the mounting operation after the predetermined timing.

2. The component mounter according to claim 1, wherein the fluid pressure circuit is opened to an outside as the nozzle moves toward the holder by a predetermined amount.

3. The component mounter according to claim 1, wherein the determination section sets the threshold by using an equation representing a relationship between the pressure or the flow rate detected by the sensor at the predetermined timing and the threshold.

4. The component mounter according to claim 1, wherein a negative pressure is supplied to the fluid pressure circuit.

5. The component mounter according to claim 1, wherein the mounting head is a rotary head in which the multiple holders are disposed on a circumference and which is rotatable in a circumferential direction.

6. A contact determination method to be applied to a component mounter that includes a head including multiple holders each relatively and movably holding a nozzle and sequentially performs mounting operations of mounting components picked up by multiple nozzles on a board, the component mounter including a fluid pressure circuit connected to the multiple holders and a sensor configured to detect at least one of a pressure and a flow rate of a fluid flowing through the fluid pressure circuit, the contact determination method being for determining whether the component picked up by the nozzle is in contact with the board, the contact determination method comprising:
setting a threshold such that the threshold increases as an absolute value of a pressure or a flow rate detected by the sensor at a predetermined timing increases; and
determining that the component picked up by the nozzle is in contact with the board when the absolute value of the pressure detected by the sensor, an absolute value of a change amount of the detected pressure, or an absolute value of the detected flow rate or a change amount of the detected flow rate exceeds the threshold during the mounting operation after the predetermined timing.
